(19) United States
(12) Patent Application Publication
(10) Pub. No.: US 2024/0123630 A1
(43) Pub. Date: Apr. 18, 2024

(54) GRIPPING APPARATUS AND AUTONOMOUS MOBILE ROBOT

(71) Applicant: SEMES CO., LTD., Chungcheongnam-do (KR)

(72) Inventors: Seung Chan LEE, Seung Chan (KR); Ho Young LEE, Gyeonggi-do (KR)

(21) Appl. No.: 18/083,470

(22) Filed: Dec. 16, 2022

(30) Foreign Application Priority Data
Oct. 18, 2022 (KR) 10-2022-0133662

(51) Int. Cl. B25J 15/00; B25J 5/00; B25J 11/00; H01L 21/687

(52) U.S. Cl. CPC B25J 15/0052; B25J 5/00; B25J 11/0095; B25J 15/0028; H01L 21/68707

(57) ABSTRACT

One aspect of the gripping apparatus for gripping a gripping object provided with a head unit, in which a fitting groove is formed, of the present invention for achieving the above object comprises a base unit made of a frame, plate, box, or a combination thereof; a first gripper including a first distal end unit bent corresponding to the fitting groove, wherein a separation distance of the first distal end unit is adjusted at the base unit, and a plurality of first grippers facing each other are provided; a second gripper located outside the first gripper and including a second distal end unit bent toward a lower edge of the gripping object, wherein a separation distance of the second distal end unit is adjusted at the base unit, and a plurality of a second grippes facing each other are provided; an adjusting unit provided in the base unit and for adjusting a separation distance of the first distal end units of the plurality of first grippers and a separation distance of the second end units of the plurality of second grippers; and a vertical driving unit for manipulating the adjusting unit.

This application claims the benefit of Korean Patent Application No. 10-2022-0133662, filed on Oct. 18, 2022, in the Korean Intellectual Property Office, the disclosure of which is incorporated herein by reference in its entirety.

### BACKGROUND

### 1. Field

The present invention relates to a gripping apparatus and an autonomous driving robot including the same.

### 2. Description of the Related Art

Semiconductor devices, such as integrated circuit devices, can generally be formed by repeatedly performing a series of processing processes on a substrate, such as a silicon wafer. For example, a semiconductor device may be formed on the substrate by repeatedly performing a deposition process for forming a film on a substrate, an etching process for forming a pattern so that the film has electrical properties, an ion implantation process or diffusion process for implanting or diffusing impurities into the pattern, and cleaning and rinsing processes for removing impurities from the patterned substrate.

After the semiconductor device is formed, an electrical inspection process for inspecting electrical characteristics of the semiconductor device may be performed. The inspection process may be performed by a probe station including a probe card having a plurality of probes, and a test head for providing electrical signals to semiconductor devices and analyzing output signals from the semiconductor devices to inspect electrical characteristics of semiconductor devices may be docked in an upper portion of a body of the probe station, on which the probe card is mounted,

### SUMMARY

On the other hand, a probe card weighs a lot like 25 kg and are difficult to transport by hand, so improvement is needed for work efficiency.

An object of the present invention is to provide a gripping apparatus capable of gripping and transporting a gripping object provided in a semiconductor factory, such as a probe card or a FOUP, and an autonomous driving robot including the same.

The objects of the present invention are not limited to the objects mentioned above, and other objects not mentioned will be clearly understood by those skilled in the art from the following description.

One aspect of the gripping apparatus of the present invention for achieving the above other object comprises, in a gripping apparatus for gripping a gripping object provided with a head unit, in which a fitting groove is formed, a base unit made of a frame, plate, box, or a combination thereof; a first gripper including a first distal end unit bent corresponding to the fitting groove, wherein a separation distance of the first distal end unit is adjusted at the base unit, and a plurality of first grippers facing each other are provided; a second gripper located outside the first gripper and including a second distal end unit bent toward a lower edge of the gripping object, wherein a separation distance of the second distal end unit is adjusted at the base unit, and a plurality of a second grippes facing each other are provided; an adjusting unit provided in the base unit and for adjusting a separation distance of the first distal end units of the plurality of first grippers and a separation distance of the second end units of the plurality of second grippers; and a vertical driving unit for manipulating the adjusting unit.

One aspect of the autonomous driving robot of the present invention for achieving the above other object comprises a driving vehicle for transporting a gripping object provided with a head unit having a fitting groove formed from a first place to a second place; and a gripping apparatus provided in the driving vehicle and for gripping the gripping object, wherein the gripping apparatus comprises, a base unit made of a frame, plate, box, or a combination thereof; a first gripper including a first distal end unit bent corresponding to the fitting groove, wherein a separation distance of the first distal end unit is adjusted at the base unit, and a plurality of first grippers facing each other are provided; a second gripper located outside the first gripper and including a second distal end unit bent toward a lower edge of the gripping object, wherein a separation distance of the second distal end unit is adjusted at the base unit, and a plurality of second grippers facing each other are provided; an adjusting unit provided in the base unit and for adjusting a separation distance of the first distal end units of the plurality of first grippers and a separation distance of the second distal end units of the plurality of second grippers; and a vertical driving unit for manipulating the adjusting unit.

One aspect of the gripping apparatus of the present invention for achieving the above another object comprises, in gripping apparatus for gripping a gripping object including a probe card provided with a plurality of chips, and having a head unit protruded by a fitting groove concave inward from a center, a base unit made of a frame, plate, box, or a combination thereof; a plurality of first grippers provided to be slidable in a horizontal direction at the base unit and including a first distal end unit bent corresponding to the fitting groove and a first inclined surface; a plurality of second grippers located outside the first grippers, provided with a second shaft to axially rotate at the base unit, and including a second distal end unit bent toward a lower edge of the probe card, and having a second inclined surface; a vertical driving unit including a screw unit extending in a vertical direction with respect to the base unit and having a first screw thread formed on a circumferential surface thereof, a guide unit provided in parallel to and adjacent to the screw unit, and a motor for rotating the screw unit; an adjusting unit, through which the guide unit passes, and engaged with the first screw thread of the screw unit, and comprising a first block member having a first taper having a cross-sectional area decreasing toward a lower portion and located between the plurality of first grippers and a second block member having a second taper in contact with the second inclined surface and having a cross-sectional area decreasing toward an upper portion and located between the plurality of second grippers; a pressing unit including a linear guide having a length formed along a movement direction of the first gripper and passing through the first gripper and an electric spring, in which one end is supported or connected to an end of the linear guide, and the other end is provided outside the plurality of first grippers to elastically press the first gripper; a sliding unit provided between the first gripper and the first block member, and including an LM guide unit for supporting sliding of the first gripper; and a tension unit having one end connected to the base unit and the other end connected to a pair of second grippers and for supporting the pair of second grippers in an upward direction, wherein the adjusting unit moves up and down according to rotation of the motor, and a position of the first inclined surface in contact with the first taper of the first block member is changed to adjust a separation distance of the plurality of first grippers, or a position of the second inclined surface in contact with the second taper of the second block member is changed to adjust a separation distance of the plurality of second grippers.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram illustrating an autonomous driving robot according to some embodiments of the present invention;

FIG. 2 is a view showing a gripping apparatus according to a first embodiment of the present invention;

FIG. 3 is a view illustrating a state, in which a pair of first grippers of the gripping apparatus according to the first embodiment of the present invention are spaced apart from each other;

FIG. 4 is a view illustrating a state, in which a pair of first grippers of the gripping apparatus according to the first embodiment of the present invention approaches to each other;

FIG. 5 is a view illustrating a state, in which a pair of second grippers of the gripping apparatus according to the first embodiment of the present invention are spaced apart from each other;

FIG. 6 is a view illustrating a state, in which a pair of second grippers of the gripping apparatus according to the first embodiment of the present invention approaches to each other.

FIG. 7 is a view showing an adjusting unit of the gripping apparatus according to the first embodiment of the present invention;

FIG. 8 is a view showing a state, in which the adjusting unit of the gripping apparatus according to the first embodiment of the present invention is moved; and

FIG. 9 is a view illustrating a first gripper of a gripping apparatus according to a second embodiment of the present invention.

### DETAILED DESCRIPTION

Hereinafter, preferred embodiments of the present invention will be described in detail with reference to the accompanying drawings. Advantages and features of the present invention and methods of achieving them will become apparent with reference to the embodiments described below in detail in conjunction with the accompanying drawings. However, the present invention is not limited to the embodiments described below, but may be implemented in various different forms, and these embodiments are provided to make the description of the present invention complete, and fully inform those skilled in the art, to which the present invention pertains on the scope of the invention, and the present invention is only defined by the scope of the claims. Like reference numerals refer to like elements throughout.

The terminology used herein is for the purpose of describing the embodiments and is not intended to limit the present invention. In this specification, the singular also includes the plural, unless specifically stated otherwise in the phrase. As used herein, “comprises” and/or “comprising” means that components, steps, operations and/or elements mentioned does not exclude the presence or the addition of one or more other components, steps, operations and/or elements.

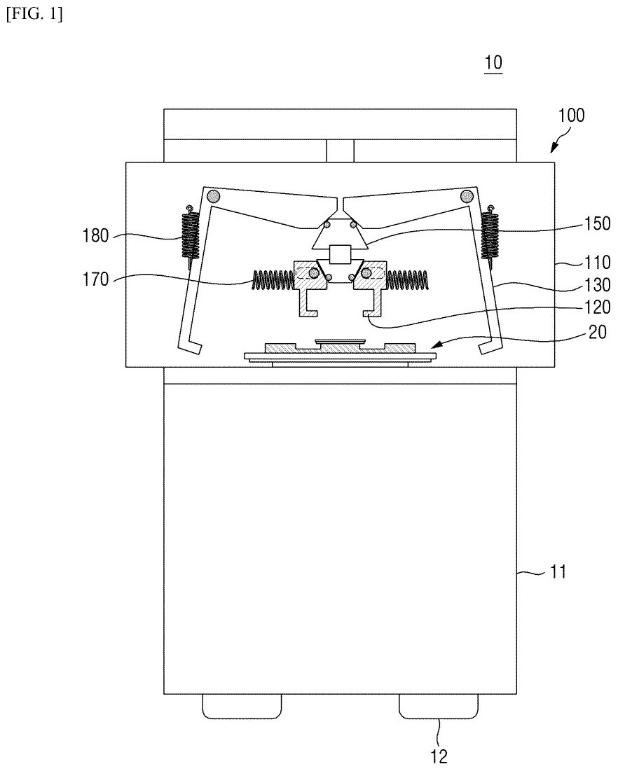

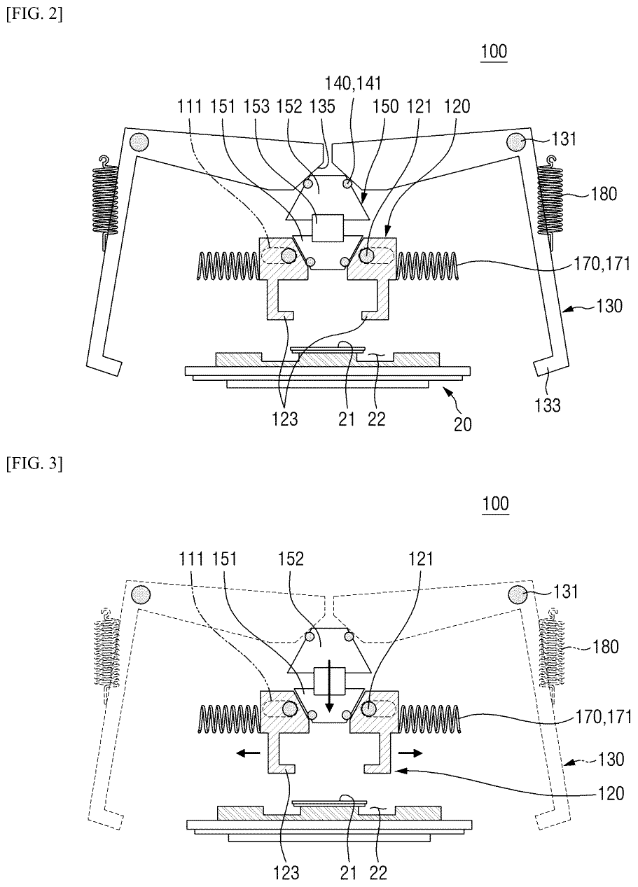

FIG. 1 is a diagram illustrating an autonomous driving robot according to some embodiments of the present invention, and FIG. 2 is a diagram illustrating a gripping apparatus according to a first embodiment of the present invention. And FIGS. 3 to 8 are views for describing the operation of the gripping apparatus according to the first embodiment of the present invention.

Referring to FIGS. 1 to 8, the autonomous driving robot 10 according to the first embodiment of the present invention may include a driving vehicle 11 and a gripping apparatus 100. The autonomous driving robot 10 may grip and transport the gripping object 20. The gripping object 20 may be, for example, a FOUP with a wafer or a probe card with a chip.

Hereinafter, the gripping object 20 will be described using a probe card as an example. The gripping object 20 provided as a probe card may be provided with a head unit 21, in which a fitting groove 22 is formed. However, the autonomous driving robot 10 of this embodiment grips various types of probe cards, and the fitting groove 22 and the head unit 21 may be omitted (see FIG. 5).

The driving vehicle 11 may transport the gripping object 20 from the first place to the second place. For example, the first place may be a point where the movement of the gripping object 20 starts and may be a stocker. The second place may be a point where the movement of the gripping object 20 ends and may be a probe station.

The driving vehicle 11 may be driven in a state, in which a plurality of wheels 12 are formed and in contact with the ground. The driving vehicle 11 may be controlled by a control unit including data of the first place and the second place, and the autonomous driving function may be mounted thereto to move or stop autonomously. The gripping apparatus 100 may be provided in the driving vehicle 11.

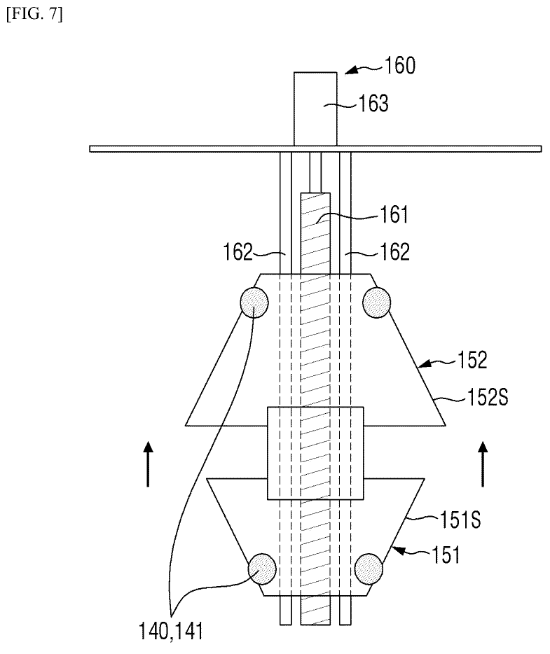

Referring to FIG. 2, the gripping apparatus 100 may include a base unit 110 (see FIG. 1), a first gripper 120, a second gripper 130, a sliding unit 140, an adjusting unit 150, a vertical driving unit 160 (see FIG. 7), a pressing unit 170, and a tensioning unit 180. Briefly, the gripping apparatus 100 may grip the gripping object 20 in two ways, thereby grip the gripping object 20 in various forms.

The base unit 110 may be made of a frame, a plate, a box, or a combination thereof. In the base unit 110, a guide hole 111 may be formed such that the first shaft 121 of the first gripper 120 moves in a horizontal direction. A minor axis of the guide hole 111 may be the same as a diameter of the first shaft 121. The major axis of the guide hole 111 may be formed corresponding to a movement length of the first shaft 121.

The first gripper 120 is configured to grip the central portion of the gripping object 20. For example, a plurality of first grippers 120 are provided to face each other, so that the plurality of first grippers 120 interfere/fit into the fitting groove 22 of the gripping object 20 to grip the head unit 21.

Various modifications are possible, such as a pair of first grippers 120 facing each other, three facing each other, or two pairs facing each other are provided. Hereinafter, a pair of first grippers 120 will be described for convenience of description and understanding.

The first gripper 120 may be provided at the base unit 110 to be capable of sliding in a horizontal direction, axial rotation, or both axial rotation and horizontal sliding to adjust the separation distance. Hereinafter, an example, in which the first gripper 120 performs axial rotation and horizontal sliding, will be described.

The first gripper 120 may be provided with a first shaft 121 supporting axial rotation. The first shaft 121 may penetrate so that it can be moved through the major axis length range of the guide hole 111 in the horizontal direction and axially rotated. However, the present invention is not limited thereto, and as another example, the first shaft 121 is provided at the base unit 110 and the first gripper 120 may be penetrated so that the first shaft 121 moves and axially rotates.

The pair of first grippers 120 may have a first inclined surface 125 having an inclination corresponding to the first taper 151S of the first block member 151 formed in an upper portion so that the separation distance is adjusted by the operation of the adjusting unit 150.

The first gripper 120 may include a first distal end unit 123 bent to correspond to the fitting groove 22 in order to grip the gripping object 20. The first distal end unit 123 may be provided in a lower portion of the first gripper 120. The first gripper 120 may grip the gripping object 20 by adjusting the separation distance of the first distal end unit 123.

The second gripper 130 is configured to grip the edge of the gripping object 20. A plurality of second grippers 130 may be provided to face each other in the same or similar manner to the first gripper 120. Hereinafter, a pair of second grippers 130 will be described for convenience of description and understanding.

The second gripper 130 may be provided at the base unit to be capable of sliding in a horizontal direction, axial rotation, or both axial rotation and horizontal sliding to adjust the separation distance, and may be located outside the first gripper 120. Hereinafter, an example, in which the second gripper 130 is axially rotated, will be described.

The second gripper 130 may be provided with a second shaft 131 supporting axial rotation. In this case, the second shaft 131 may pass through the base unit 110 so that the second shaft 131 axially rotates. However, the present invention is not limited thereto, and various modifications are possible, such as, as another example, the second shaft 131 may be provided at the base unit 110, and the second shaft may pass through the second gripper 130.

The pair of second grippers 130 may contact the second taper 152S of the second block member 152 so that the separation distance is adjusted by the operation of the adjusting unit 150, and the second inclined surface 135 having an inclination in the direction opposite to the first inclined surface 125 may be formed therein.

The second gripper 130 may include a second distal end unit 133 bent toward the lower edge of the gripping object 20. The second distal end unit 133 may be provided in a lower portion of the second gripper 130. The second gripper 130 may grip the gripping object 20 by adjusting the separation distance of the second distal end unit 133.

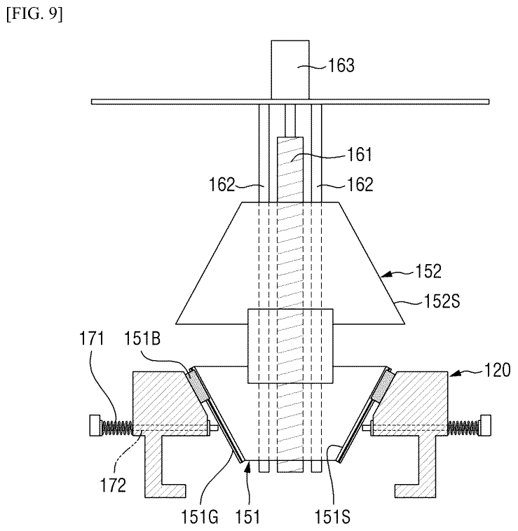

The sliding unit 140 is configured to support the sliding of the first gripper 120 and/or the second gripper 130, and may include a ball bearing 141. The ball bearing 141 may be provided between the first gripper 120 and the adjusting unit 150. The ball bearing 141 may be provided between the second gripper 130 and the adjusting unit 150. The ball bearing 141 may be provided in a ball shape, and may slide so that the first gripper 120 and/or the second gripper 130 in contact with the ball bearing 141 can easily move. However, the sliding unit 140 is not limited to the ball bearing 141, and another example will be described with reference to FIG. 9.

The adjusting unit 150 may adjust the separation distance between a pair of first grippers 120 facing each other or may adjust the separation distance between a pair of second grippers 130 facing each other. For example, the adjusting unit 150 may adjust the separation distance between the first distal end units 123 of the pair of first grippers 120 facing each other. In addition, the adjusting unit 150 may adjust the separation distance between the second distal end units 133 of the pair of second grippers 130 facing each other.

The adjusting unit 150 may be installed in the vertical driving unit 160 at the base unit 110. The adjusting unit 150 may include a first block member 151 and a second block member 152.

The first block member 151 may have a first taper 151S whose cross-sectional area decreases toward the lower portion. The first block member 151 may be located between the pair of first grippers 120.

The second block member 152 may have a second taper 152S whose cross-sectional area decreases toward the upper portion. The second block member 152 may be located between the pair of second grippers 130 in the upper portion of the first block member 151.

In addition, the adjusting unit 150 may further include a nut member 153. The nut member 153 has a screw thread engaged with the first screw thread of the screw unit 161 on the inner circumferential surface, and can move in association with the rotation of the screw unit 161.

However, various modifications are possible such as the nut member 153 is omitted, and a screw thread engaging with the first screw thread of the screw unit 161 may be formed in each of the first block member 151 and the second block member 152.

The vertical driving unit 160 may operate the adjusting unit 150.

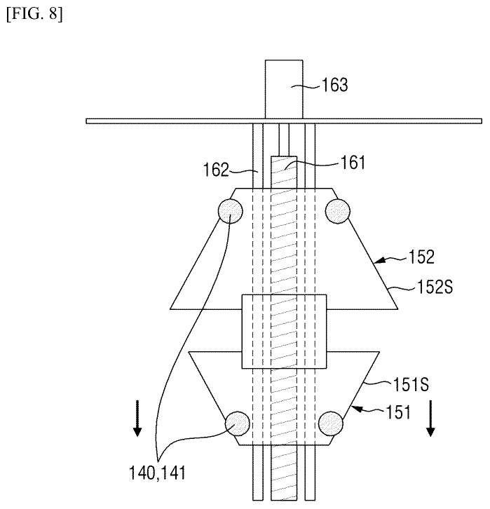

For example, referring to FIGS. 7 and 8, the vertical driving unit 160 may include a screw unit 161, a guide unit 162, and a motor 163.

The screw unit 161 may extend in a vertical direction (up and down direction) with respect to the base unit 110, and a first screw thread (not shown) may be formed on the circumferential surface. The adjusting unit 150 may be engaged with the first screw thread to be coupled to the screw unit 161.

The guide unit 162 may be provided adjacent to and parallel to the screw unit 161. The guide unit 162 may pass through the adjusting unit 150 to guide the movement of the adjusting unit 150. For example, the adjusting unit 150 engaged with the first screw thread may be operated in association with the first screw thread by rotation of the screw unit 161. At this time, the guide unit 162 may block the rotation of the adjusting unit 150, so that the adjusting unit 150 may move in the vertical direction along the guide unit 162 without rotation.

The motor 163 may rotate the screw unit 161 so that the adjusting unit 150 moves. For example, the shaft of the motor 163 may be connected to the screw unit 161 to directly transmit the rotational force of the motor 163 to the screw unit 161.

As another example, the motor 163 may include a first gear (not shown) connected to the screw unit 161, a second gear (not shown) paired with the first gear and connected to the shaft of the motor 163, and a driving belt (not shown) connecting the first gear (not shown) and the second gear (not shown). When the motor 163 is driven, the rotational force of the second gear connected to the motor 163 may be transmitted to the first gear by the driving belt to rotate the screw unit 161. In addition, various modifications are possible.

Referring back to FIG. 2, the pressing unit 170 is configured to make the pair of first grippers 120 be in close contact with the adjusting unit 150. The pressing unit 170 may have one end connected to the base unit 110 and the other end provided outside the pair of first grippers 120 to press the pair of first grippers 120 in a direction, in which they approach to each other. However, various modifications are possible such as the pressing unit 170 is not directly connected to the base unit 110, and it may be supported by a linear guide 172 (see FIG. 9) to be described later.

The pressing unit 170 presses with a pressing force lower than the pressing force of the adjusting unit 150 to prevent the first gripper 120 from deviating from the design position while allowing movement of the first gripper 120 by the adjusting unit 150.

For example, the pressing unit 170 may include an elastic spring 171. However, the present invention is not limited thereto, and the pressing unit 170 may include a jack as an actuator using pneumatic or hydraulic pressure. When the pressing unit 170 presses the first gripper 120 with pneumatic or hydraulic pressure, the degree of pressurization by the pneumatic/hydraulic pressure may be controlled by the control unit in connection with the position of the adjusting unit 150. However, the present invention is not limited thereto.

The tension unit 180 may have one end connected to the base unit 110 and the other end connected to the pair of second grippers 130 to support the pair of second grippers 130 in an upward direction.

For example, the tension unit 180 may include a tension spring. The tension spring may prevent the second gripper 130 from colliding with the gripping object 20 by pulling the second gripper 130 in an upward direction. In addition, the tensile force (which may include tension) of the tension unit 180 is formed to be smaller than the size at which the second block member 152 pushes the pair of second grippers 130, so that it may allow the closing operation of the pair of second grippers 130 by the second block member 152. Here, the closing operation may mean that the separation distance of the second distal end units 133 is reduced.

In contrast, the tension unit 180 may include a wire, and the tension unit 180 may support the second gripper 130 in an upward direction by adjusting the amount of winding of the wire. Various modifications are possible such as the amount of winding of the wire is controlled so that the set tension is maintained, so that sagging of the second distal end unit 133 can be prevented.

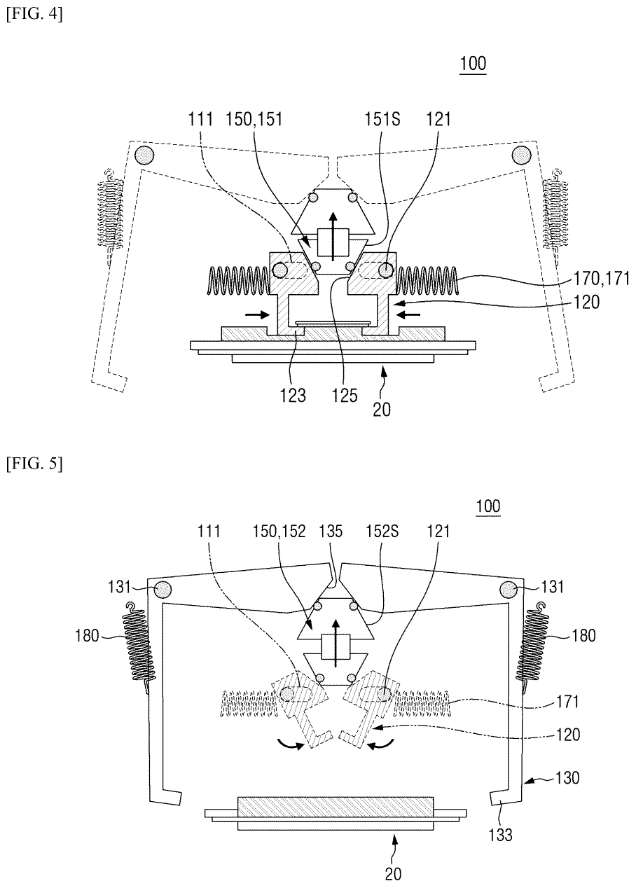

Hereinafter, a gripping operation of the first gripper 120 for gripping the head unit 21 of the gripping object 20 will be described with reference to FIGS. 3 and 4.

Referring to FIG. 3, the pair of first grippers 120 may be spaced apart so that the first distal end unit 123 is inserted into the fitting groove 22.

To this end, the vertical driving unit 160 is operated, that is, the screw unit 161 is rotated in the first direction by the driving of the motor 163, and in conjunction with this, the adjusting unit 150 may be lowered to a lower portion along the guide unit 162.

When the first taper 151S of the first block member 151 is lowered, since the cross-sectional area of the first taper 151S at the position in contact with the first inclined surface 125 increases, that is, the width between the pair of first grippers 120 increases, and the pair of first grippers 120, in which the first inclined surface 125 is formed along the first taper 151S, may be pushed away from each other.

Here, the separation distance between the pair of first distal end units 123 may be a distance, at which the first distal end unit 123 is inserted into the fitting groove 22 without interfering with the head unit 21. As such, after the distance is adjusted so that the first distal end unit 123 is inserted into the fitting groove 22 without being caught in the head unit 21, for example, the base unit 110 may be lowered in the downward direction so that the first distal end unit 123 can be inserted into the fitting groove 22.

Referring to FIG. 4, the separation distance between the first distal end unit 123 is reduced, and the head unit 21 may be gripped.

To this end, the vertical driving unit 160 is operated, that is, the screw unit 161 is rotated in the second direction by the driving of the motor 163, so that the adjusting unit 150 may be raised to an upper portion along the guide unit 162.

When the first taper 151S of the first block member 151 is raised, the cross-sectional area of the first taper 151S at the position in contact with the first inclined surface 125 decreases, that is, the width between the pair of first grippers 120 is reduced, and since the pressing unit 170 elastically presses, and the first inclined surface 125 is pushed along the first taper 151S so that the pair of first distal end units 123 may approach to each other.

In this way, the gripping object 20 may be gripped by adjusting the separation distance of the pair of first distal end units 123. In addition, the gripping state may be released by performing an operation opposite to the above-mentioned series of operations.

In addition, the vertical movement of the adjusting unit 150 for the gripping operation of the first gripper 120 may be performed in a range, in which the closing operation of the pair of second grippers 130 is not performed. This is to prevent the second gripper 130 from interfering with the gripping object 20. Accordingly, regardless of the operation of the pair of second grippers 130, if the second gripper 130 does not interfere with the gripping object 20, various modifications are possible such as the vertical movement of the adjusting unit 150 for the gripping operation of the first gripper 120 can be made even in a state, in which the closing operation of the second gripper 130 is performed.

When the vertical movement of the adjusting unit 150 for the gripping operation of the first gripper 120 is performed in a range, in which the closing operation of the pair of second grippers 130 is not performed, it is as follows.

For example, in a state, in which the first gripper 120 is operated, the highest height of the adjusting unit 150 may be the first position, which is a state, in which the pair of first grippers 120 grip the head unit 21 (see FIG. 4).

Meanwhile, at the second position higher than the first position, the first distal end unit 123 may be axially rotated and closed. This may be independent of a state, in which the first gripper 120 grips the head unit 21. That is, since the first distal end unit 123 may be in a closed state to stand by so that the gripping operation of the second gripper 130 is performed, it will be described separately from the gripping operation of the first gripper 120.

The second position of the adjusting unit 150 is higher than the first position, and it may be a state, in which the first distal end unit 123 is in a standby state without performing an operation, and the pair of second grippers 130 may be in an open state in a range that does not interfere with the gripping object 20 (see FIG. 5).

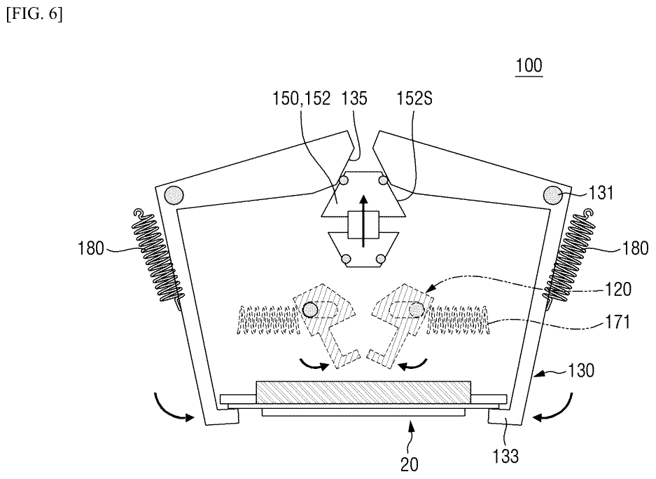

The third position of the adjusting unit 150 is a position higher than the second position, and it may be a state, in which the first distal end unit 123 is out of influence from the operation of the adjusting unit 150, and it may be a state, in which the second gripper 130 grips the gripping object 20 (see FIG. 6).

In addition to these second and third positions, a gripping operation of the second gripper 130 for gripping the edge of the gripping object 20 will be described with reference to FIGS. 5 and 6.

Referring to FIG. 5, the pair of second grippers 130 may be in a wider state than the edge of the gripping object 20.

For example, the screw unit 161 is further rotated in the second direction so that the adjusting unit 150 is located at a second position higher than the first position by driving the motor 163, so that the adjusting unit 150 may be raised along a guide unit 162.

When the adjusting unit 150 may be raised from the first position to the second position, the cross-sectional area of the first taper 151S at the position in contact with the first inclined surface 125 becomes smaller, that is, the width between the pair of first grippers 120 becomes smaller, in this case, since the pressing unit 170 elastically presses, the pair of first distal end units 123 may be closed by axial rotation.

In this case, the pair of second grippers 130 may be in a state, in which they are more closed by the adjusting unit 150 at the second position than by the adjusting unit 150 at the first position, but may be in a state wider than the edge of the gripping object 20. In addition, the second gripper 130 may be pulled upward by the tension unit 180, so that the second gripper 130 may be elastically supported in an upward direction.

Referring to FIG. 6, when the adjusting unit 150 is raised to the third position higher than the second position, that is, the screw unit 161 is rotated more in the second direction, so that the adjusting unit 150 can be further raised along the guide unit 162.

Then, since the cross-sectional area of the second taper 152S at the position in contact with the second inclined surface 135 becomes larger, that is, the width between the pair of second grippers 130 becomes larger, so that the pair of second distal end units 133 may be closed by axial rotation. At this time, the gripping object 20 is placed between the pair of second distal end units 133, so that the gripping object 20 may be gripped by the pair of second grippers 130. In addition, the gripping state may be released by performing an operation opposite to the above-mentioned series of operations.

Hereinafter, a modified example of the present embodiment will be described with reference to FIG. 9, and overlapping descriptions of the same configuration having the same function will be omitted.

FIG. 9 is a view illustrating a first gripper of a gripping apparatus according to a second embodiment of the present invention. With reference to FIG. 9, points different from those described with reference to FIGS. 2 to 8 will be mainly described.

Referring to FIG. 9, the gripping apparatus 100 of the second embodiment may include a base unit 110, a first gripper 120, a second gripper 130, a sliding unit 140, the adjusting unit 150, the vertical driving unit 160, the pressing unit 170, and the tension unit 180 in the same way as or similarly to the first embodiment.

However, the sliding unit 140 of this embodiment is different from the first embodiment mentioned above in that it includes an LM guide unit. In addition, the pressing unit 170 of the present embodiment is different in that the linear guide 172 is further provided. However, another embodiment is possible by combining any one or more of the first and second embodiments and known techniques. For example, as the linear guide 172 of the second embodiment may be included in the first embodiment, various modifications are possible as long as it does not conflict with the present invention.

First, the LM guide units 151G and 151B may include an LM guide 151G and an LM block 151B.

The LM guide 151G may be provided in the first taper 151S of the first block member 151 to form a movement path of the LM block 151B. For example, the LM guide 151G may be provided in a rail structure extending in an inclined direction of the first taper 151S. The LM block 151B may be slid along the LM guide 151G. The LM block 151B may be in contact with the first gripper 120 to facilitate sliding of the first gripper 120 with respect to the first taper 151S. In addition, the LM block 151B may be provided in a form fixed to the first inclined surface 125 of the first gripper 120, but is not limited thereto.

And in the present embodiment, the LM guide units 151G, 151B are illustrated as being provided in the first block member 151, but the LM guide units 151G, 151B are configurations that facilitates sliding, and may be provided in the second block member 152. In addition, various modifications are possible such as the LM guide units 151G and 151B can be installed in the first block member 151 and the ball bearing 141 can be installed in the second block member 152.

The linear guide 172 may have a length formed along the movement direction of the first gripper 120. The linear guide 172 may guide the elastic direction of the elastic spring 171. In addition, the linear guide 172 may pass through the first gripper 120 to guide the movement path of the first gripper 120.

However, since the present invention is not limited thereto, other modifications, in which the linear guide 172 does not pass through the first gripper 120, are possible. That is, the linear guide 172 may guide the elastic direction of the elastic spring 171 and may not guide the movement path of the first gripper 120. In this case, the first gripper 120 may have a structure for axial rotation as in the first embodiment.

Although the embodiments of the present invention have been described above with reference to the accompanying drawings, the present invention is not limited to the above embodiments, but may be manufactured in a variety of different forms, and those of ordinary skill in the art to which the present invention pertains can understand that the present invention may be embodied in other specific forms without changing the technical spirit or essential features of the present invention. Therefore, it should be understood that the embodiments described above are illustrative in all respects and not limiting.

### REFERENCE NUMERAL

10: autonomous driving robot
100: gripping object
110: base unit
120: first gripper
130: second gripper
150: adjusting unit
160: vertical driving unit

What is claimed is:

1. A gripping apparatus for gripping a gripping object provided with a head unit, in which a fitting groove is formed, comprising:
a base unit made of a frame, plate, box, or a combination thereof;
a first gripper including a first distal end unit bent corresponding to the fitting groove, wherein a separation distance of the first distal end unit is adjusted at the base unit, and a plurality of first grippers facing each other are provided;
a second gripper located outside the first gripper and including a second distal end unit bent toward a lower edge of the gripping object, wherein a separation distance of the second distal end unit is adjusted at the base unit, and a plurality of a second grippes facing each other are provided;
an adjusting unit provided in the base unit and for adjusting a separation distance of the first distal end units of the plurality of first grippers and a separation distance of the second end units of the plurality of second grippers; and
a vertical driving unit for manipulating the adjusting unit.

2. The gripping apparatus of claim 1, wherein the first gripper is provided at the base unit to be capable of axial rotation, sliding in a horizontal direction, or both axial rotation and sliding in a horizontal direction,
wherein any one of the base unit and the first gripper is provided with a first shaft supporting axial rotation of the first gripper, and the first shaft passes through the other one so that the first shaft moves in a horizontal direction and axially rotates,
wherein any one of the base unit and the second gripper is provided with a second shaft, and the second shaft is connected to the other one so that the second gripper is provided at the base unit to be capable of axial rotation.

3. The gripping apparatus claim 2, wherein, in the base unit or the first gripper, a guide hole having a length of a minor axis the same as a diameter of the first shaft and a length of a major axis corresponding to a movement length of the first shaft in a horizontal direction is formed so that the first shaft moves in a horizontal direction.

4. The gripping apparatus claim 1, wherein the adjusting unit comprises a first block member having a first taper having a cross-sectional area decreasing toward a lower portion and located between the plurality of first grippers and a second block member having a second taper having a cross-sectional area decreasing toward an upper portion and located between the plurality of second grippers in an upper portion of the first block member,
wherein the first gripper has a first inclined surface having an inclination corresponding to the first taper,
wherein the second gripper has a second inclined surface having an inclination in a direction opposite to the first inclined surface.

5. The gripping apparatus of claim 4, wherein the vertical driving unit comprises,
a screw unit extending in a vertical direction with respect to the base unit and having a first screw thread formed on a circumferential surface thereof, wherein the adjusting unit is engaged with the first screw thread and coupled thereto;
a guide unit provided in parallel to and adjacent to the screw unit, wherein the guide unit passes through the adjusting unit to guide vertical movement of the adjusting unit; and
a motor for rotating the screw unit to move the adjusting unit.

6. The gripping apparatus of claim 1 further comprises,
a pressing unit provided outside the plurality of first grippers to press in a direction, in which the plurality of first grippers are approached, and for pressing with a pressing force lower than a pressing force of the adjusting unit to allow movement of the first grippers by the adjusting unit.

7. The gripping apparatus of claim 6 further comprise,
a tension unit having one end connected to the base unit and the other end connected to the plurality of second grippers and for supporting the plurality of second grippers in an upward direction.

8. The gripping apparatus of claim 7, wherein the pressing unit comprises a linear guide having a length along a movement direction of the first gripper, and an elastic spring for elastically pressing at the linear guide or an actuator,
wherein the tension unit is provided with any one of a tension spring or a wire.

9. The gripping apparatus of claim 1 further comprises,
a sliding unit provided between the first gripper and the adjusting unit and between the second gripper and the adjusting unit, and including a ball bearing or an LM guide unit for supporting sliding of the first gripper and the second gripper.

10. The gripping apparatus of claim 1, wherein the gripping object comprises a probe card with a chip or a FOUP with a wafer.

11. An autonomous driving robot comprising:
a driving vehicle for transporting a gripping object provided with a head unit having a fitting groove from a first place to a second place; and
a gripping apparatus provided in the driving vehicle and for gripping the gripping object,
wherein the gripping apparatus comprises,
a base unit made of a frame, plate, box, or a combination thereof;
a first gripper including a first distal end unit bent corresponding to the fitting groove, wherein a separation distance of the first distal end unit is adjusted at the base unit, and a plurality of first grippers facing each other are provided;
a second gripper located outside the first gripper and including a second distal end unit bent toward a lower edge of the gripping object, wherein a separation distance of the second distal end unit is adjusted at the base unit, and a plurality of second grippers facing each other are provided;
an adjusting unit provided in the base unit and for adjusting a separation distance of the first distal end units of the plurality of first grippers and a separation distance of the second distal end units of the plurality of second grippers; and
a vertical driving unit for manipulating the adjusting unit.

12. The autonomous driving robot of claim 11, wherein the first gripper is provided at the base unit to be capable of axial rotation, sliding in a horizontal direction, or both axial rotation and sliding in a horizontal direction,
wherein any one of the base unit and the first gripper is provided with a first shaft supporting axial rotation of the first gripper, and the first shaft passes through the other one so that the first shaft moves in a horizontal direction and axially rotates,
wherein any one of the base unit and the second gripper is provided with a second shaft, and the second shaft is connected to the other one so that the second gripper is provided at the base unit to be capable of axial rotation.

13. The autonomous driving robot of claim 12, wherein, in the base unit or the first gripper, a guide hole having a length of a minor axis the same as a diameter of the first shaft and a length of a major axis corresponding to a movement length of the first shaft in a horizontal direction is formed so that the first shaft moves in a horizontal direction.

14. The autonomous driving robot of claim 11, wherein the adjusting unit comprises a first block member having a first taper having a cross-sectional area decreasing toward a lower portion and located between the plurality of first grippers and a second block member having a second taper having a cross-sectional area decreasing toward an upper portion and located between the plurality of second grippers in an upper portion of the first block member,
wherein the first gripper has a first inclined surface having an inclination corresponding to the first taper,
wherein the second gripper has a second inclined surface having an inclination in a direction opposite to the first inclined surface.

15. The autonomous driving robot of claim 14, wherein the vertical driving unit comprises,
a screw unit extending in a vertical direction with respect to the base unit and having a first screw thread formed on a circumferential surface thereof, wherein the adjusting unit is engaged with the first screw thread and coupled thereto;
a guide unit provided in parallel to and adjacent to the screw unit, wherein the guide unit passes through the adjusting unit to guide vertical movement of the adjusting unit; and
a motor for rotating the screw unit to move the adjusting unit.

16. The autonomous driving robot of claim 11 further comprises,
a pressing unit provided outside the plurality of first grippers to press in a direction, in which the plurality of first grippers are approached, and for pressing with a pressing force lower than a pressing force of the adjusting unit to allow movement of the first grippers by the adjusting unit.

17. The autonomous driving robot of claim 16 further comprise,
a tension unit having one end connected to the base unit and the other end connected to the plurality of second grippers and for supporting the plurality of second grippers in an upward direction.

18. The autonomous driving robot of claim 17, wherein the pressing unit comprises a linear guide having a length along a movement direction of the first gripper, and an elastic spring for elastically pressing at the linear guide or an actuator,
wherein the tension unit is provided with any one of a tension spring or a robot.

19. The autonomous driving robot of claim 11 further comprises,
a sliding unit provided between the first gripper and the adjusting unit and between the second gripper and the adjusting unit, and including a ball bearing or an LM guide unit for supporting sliding of the first gripper and the second gripper,
wherein the gripping object comprises a FOUP with a wafer or a probe card with a chip.

20. A gripping apparatus for gripping a gripping object including a probe card provided with a plurality of chips, and having a head unit protruded by a fitting groove concave inward from a center comprising:
a base unit made of a frame, plate, box, or a combination thereof;
a plurality of first grippers provided to be slidable in a horizontal direction at the base unit and including a first distal end unit bent corresponding to the fitting groove and a first inclined surface;
a plurality of second grippers located outside the first grippers, provided with a second shaft to axially rotate at the base unit, and including a second distal end unit bent toward a lower edge of the probe card, and having a second inclined surface;
a vertical driving unit including a screw unit extending in a vertical direction with respect to the base unit and having a first screw thread formed on a circumferential surface thereof, a guide unit provided in parallel to and adjacent to the screw unit, and a motor for rotating the screw unit;
an adjusting unit, through which the guide unit passes, and engaged with the first screw thread of the screw unit, and comprising a first block member having a first taper having a cross-sectional area decreasing toward a lower portion and located between the plurality of first grippers and a second block member having a second taper in contact with the second inclined surface and having a cross-sectional area decreasing toward an upper portion and located between the plurality of second grippers;
a pressing unit including a linear guide having a length formed along a movement direction of the first gripper and passing through the first gripper and an electric spring, in which one end is supported or connected to an end of the linear guide, and the other end is provided outside the plurality of first grippers to elastically press the first gripper;
a sliding unit provided between the first gripper and the first block member, and including an LM guide unit for supporting sliding of the first gripper; and
a tension unit having one end connected to the base unit and the other end connected to a pair of second grippers and for supporting the pair of second grippers in an upward direction,
wherein the adjusting unit moves up and down according to rotation of the motor, and a position of the first inclined surface in contact with the first taper of the first block member is changed to adjust a separation distance of the plurality of first grippers, or a position of the second inclined surface in contact with the second taper of the second block member is changed to adjust a separation distance of the plurality of second grippers.
